(19) United States
(12) Patent Application Publication
(10) Pub. No.: US 2026/0186036 A1
(43) Pub. Date: Jul. 2, 2026

(54) Testing Method and Testing Loop for Contact Resistance

(71) Applicant: Yunnan Power Grid Co., Ltd. Lijiang Power Supply Bureau, Lijiang (CN)

(72) Inventors: Chongliang ZHANG, Lijiang (CN); Jiacan WANG, Lijiang (CN); Mingya LUO, Lijiang (CN); Bingnan TANG, Lijiang (CN); Meiying HE, Lijiang (CN); Mingxian LIU, Lijiang (CN); Yu ZHANG, Lijiang (CN); Hebo PU, Lijiang (CN); Duzhilacong YASE, Lijiang (CN); Yong YANG, Lijiang (CN); Xuefeng WU, Lijiang (CN); Guangquan ZHENG, Lijiang (CN); Hongzhong ZHANG, Lijiang (CN); Chijun LI, Lijiang (CN); Shengrong CHEN, Lijiang (CN)

(21) Appl. No.: 19/425,089

(22) Filed: Dec. 18, 2025

Related U.S. Application Data
(63) Continuation of application No. PCT/CN2024/143727, filed on Dec. 30, 2024.

(51) Int. Cl. G01R 27/08

(52) U.S. Cl. CPC G01R 27/08

(57) ABSTRACT

The present disclosure relates to the technical field of resistance testing, and in particular to a testing method and a testing loop for a contact resistance, comprising exerting a given contact pressure to enable two metallic conductors to contact, and connecting two ends of a current source with a pair of leads respectively connected with two metallic conductors as an input current. The present disclosure provides a method for acquiring a contact surface temperature at different stages at different testing points, and a contact resistance value obtained through calculation is compared and verified with a contact resistance value actually tested.

### CROSS-REFERENCE TO RELATED APPLICATIONS

The present application is a continuation of International Application No. PCT/CN2024/143727, filed on Dec. 30, 2024, the entire contents of which are incorporated herein by reference.

### TECHNICAL FIELD

The present disclosure relates to the technical field of resistance testing, and in particular to a testing method and a testing loop for a contact resistance.

### BACKGROUND

Connecting hardware is mainly used to complete the connection of currents between two metallic conductors, such as connecting clips and connecting tubes. In recent years, with the increase in household appliances and the increase in the load of factory machines, the reliability of connecting hardware has been greatly challenged. Clips are crucial components for carrying currents in overhead power transmission lines. Operating in high-temperature and harsh environments for a long time, clips are prone to mechanical damage and electrical contact failure. The mechanical damage mainly manifests as deformation and fracture failure of clips. Electrical contact failure is the main failure form of connecting clips. In practical work, electrical contact failure of clips mainly manifests as continuous increase of contact resistance, and the contact surface between clips and cables is severely overheated and even burned.

During the design, installation, and operation of connecting hardware, a contact resistance is generally affected by contact forms, contact pressures, material properties, and contact surface temperatures. Excessive contact resistances can generate a large amount of Joule heat, causing material aging and combustion of an insulation layer, affecting the mechanical and electrical properties of a material, and generating large thermal stress between contact surfaces, leading to thermal expansion of metals and shortening the service life of connecting hardware, thus not only causing economic losses, but also seriously endangering personal safety.

Therefore, in order to make a contact resistance value suitable for an working environment, a testing method for the contact resistance value between conductors under different contact pressures and contact surface temperatures is required in the prior at, so as to simulate the variation range of contact resistances in a subsequent usage environment.

### SUMMARY

In the section as well as in the abstract and title of the present application, some simplifications or omissions may be made to avoid making the purpose of the section, the abstract and the title ambiguous, but such simplifications or omissions cannot be used to limit the scope of the present disclosure.

In view of the problems in the present disclosure or prior art that the contact resistance value between conductors is hard to test under different environmental conditions, the present disclosure is declared.

Therefore, one of the purposes of the present disclosure is to provide a testing method for a contact resistance.

To solve the technical problem, the present disclosure provides a technical solution as follows: a testing method for a contact resistance, for testing a contact resistance between two metallic conductors, including:
exerting a given contact pressure to enable two metallic conductors to contact;
connecting two ends of a current source with a pair of leads respectively connected with two metallic conductors as an input current;
introducing the voltage at two ends of the metallic conductors into a multimeter using another pair of leads to be tested; and
calculating a contact resistance value according to the testing result, wherein the input current is pulse current.

As a preferable solution of the testing method for the contact resistance of the present disclosure, the exerting a given contact pressure includes:
placing two metallic conductors at the working area of a press machine;
adjusting the contact surfaces of the two metallic conductors to be fitted with the pressing direction of the press machine; and
adding an insulating material in the pressing direction to isolate the press machine from the metallic conductors.

As a preferable solution of the testing method for the contact resistance of the present disclosure, further including testing the contact resistance value at different contact pressures, including,
successively increasing the contact pressure between the two metallic conductors by set gradient values;
respectively introducing different transient current values as pulse current inputs after pressure increase each time; and
taking the mean value of contact resistances tested with different transient currents as contact resistances of corresponding contact pressures.

As a preferable solution of the testing method for the contact resistance of the present disclosure, further including, recording a variation curve of tested contact resistances along with contact pressures;
taking a contact pressure range that the contact resistance trends to be stable along with the contact pressures as a working range;
a method for calculating the contact resistance value within the working range of contact pressures comprises:
calculating a contact resistance value of a single contact spot formed at the given contact pressure;
taking the combination of all contact spots formed between the two metallic conductors as a contact surface; and
calculating the total contact resistance value of the contact surface as the contact resistance value between the two metallic conductors.

As a preferable solution of the testing method for the contact resistance of the present disclosure, by taking the contact spots between the two metallic conductors as a circle, the equation for calculating the contact resistance of a single contact spot between two metallic conductors is:

$${R}_{c} = {R}_{s} + {R}_{f} = ( {ρ}_{1} + {ρ}_{2} ) / 4 r + \frac{θ}{π {r}^{2}}$$

in the equation, the first term is the calculation equation of a cold-state contraction resistance Rₛ of the two metallic conductors at 0° C.; the second term is the calculation equation of a film resistance R_{f} formed on the contact surface of the two metallic conductors; ρ₁ and ρ₂ are respectively resistivities of the two metallic conductors in mutual contact; r represents an equivalent radius of the contact spot of the two metallic conductors; and θ is a film resistivity of a pollution film on the contact surface of the two metallic conductors.

As a preferable solution of the testing method for the contact resistance of the present disclosure, the two metallic conductors both take the shape of a cylinder; the two metallic conductors are in contact in the mode of line contact between a cylindrical side surface with a cylindrical bottom surface, or surface contact between a cylindrical bottom surface with a cylindrical bottom surface;
the calculation equation of the radius r₁ of the contact surfaces of the two cylindrical metallic conductors is:

$${r}_{1} = {( 4 Pr / π {E}^{*} )}^{\frac{1}{2}}$$

in the equation, P represents a contact pressure; E* represents an equivalent elastic modulus; r represents an equivalent contact radius of a single contact spot;
the calculation equations of an equivalent elastic modulus E* and an equivalent contact radius r of the single contact spot are as follows:

$${E}^{*} = \frac{1 - {μ}_{1}^{2}}{{E}_{1}} + \frac{1 - {μ}_{2}^{2}}{{E}_{2}}$$

$$\frac{1}{r} = \frac{1}{{R}_{1}} + \frac{1}{{R}_{2}}$$

in the equation, E₁ and E₂ respectively represent elastic moduli of the two metallic conductors in contact; μ₁ and μ₂ represent the Poisson's ratio of the two conductors in contact; and R₁ and R₂ respectively represent the radii of the two cylindrical metallic conductors in mutual contact.

As a preferable solution of the testing method for the contact resistance of the present disclosure, when the two cylindrical metallic conductors are in line contact, the two metallic conductors are taken as that multiple successive equivalent contact spots are taken as the contact surfaces, and the calculation equation of the total contact resistance of the contact surfaces of the two metallic conductors at the moment is:

$${R}_{c} = {R}_{s} * \frac{b}{r}$$

in the equation, R_{c} represents the total contact resistance; Rₛ is a contraction resistance of a single contact spot; b represents the length of the contact surface; r represents the radius of the single contact spot;
the calculation equation of a hot-state contraction resistance R_{sθ} of the single contact spot is:

$${R}_{s θ} = {R}_{s 0} + ( 1 + \frac{2}{3} α T )$$

in the equation, Rₛ₀ is a cold-state contraction resistance at 0° C.; T is the contact surface temperature; and α is the temperature coefficient of the resistance.

As a preferable solution of the testing method for the contact resistance of the present disclosure, the method for acquiring a contact surface temperature includes,
enabling two metallic conductors to contact at a given contact pressure through a connecting clip; and
inputting a pulse current at two ends of the two metallic conductors, and acquiring the temperature of a testing point;
the testing point at least includes the middle of the connecting clip, and the connecting parts of the connecting clip with the two metallic conductors.

Based on the same invention concept, the present disclosure also provides a testing loop for a contact resistance, for achieving the testing method for the contact resistance, including two groups of cables to be tested, a current source for providing an input current and a multimeter for testing the voltage at two ends of the cables to be tested;
a loop is formed between the two groups of cables to be tested and the current source and the multimeter though a lead; the contact resistance is generated between the two groups of cables to be tested after in contact; and the multimeter is in parallel connection with the two groups of cables to be tested.

As a preferable solution of the testing loop for the contact resistance of the present disclosure, at least three groups of cables to be tested are set and sequentially connected through ends; two adjacent groups of cables to be tested are in connection and contact through a group of connecting clips;
the current source is a large current generator connected at the head and tail ends of the cables to be tested and connected sequentially; and each group of the connecting clips maintain two groups of cables to be tested in contact by a given contact pressure.

The present disclosure has the beneficial effects that: the present disclosure provides a method for acquiring a contact surface temperature at different stages at different testing points, and a contact resistance value obtained through calculation is compared and verified with a contact resistance value actually tested, thereby deducing calculation equations for simulating contact resistance values in usage environments at different contact pressures and different contact surface temperatures, and thus conveniently and rapidly calculating contact resistance values fitting with the usage environments.

### BRIEF DESCRIPTION OF DRAWINGS

In order to describe the technical solutions in the examples of the present disclosure more clearly, a brief description of the accompanying drawings required for describing the examples will be provided below. Obviously, the accompanying drawings in the following description show merely some examples of the present disclosure. Those of ordinary skill in the art can also derive other accompanying drawings from these accompanying drawings without making creative efforts.

FIG. 1 is a schematic diagram of testing of a contact resistance in embodiment 1 of the present disclosure;

FIG. 2 is a schematic diagram of a testing loop in embodiment 1 of the present disclosure;

FIG. 3 is a schematic diagram of variation of contact resistances along with contact pressures in embodiment 1 of the present disclosure;

FIG. 4 is a schematic diagram of variation of contact resistances along with roughness in embodiment 2 of the present disclosure;

FIG. 5 is a schematic diagram of comparison of test values and calculation values of contact resistances in embodiment 2 of the present disclosure;

FIG. 6 is a schematic diagram of testing sites of contact resistances in embodiment 3 of the present disclosure;

FIG. 7 is a schematic diagram of testing of contact resistances in embodiment 3 of the present disclosure;

FIG. 8 is a schematic diagram of a testing loop in embodiment 3 of the present disclosure;

FIG. 9 is a schematic diagram of temperature testing points of contact resistances in embodiment 3 of the present disclosure.

### DETAILED DESCRIPTION OF THE EMBODIMENTS

In order to make the aforementioned purposes, features and advantages of the present disclosure more apparent and comprehensible, detailed descriptions of specific embodiments of the present disclosure are provided below in conjunction with the appended drawings.

In the following description, numerous specific details are set forth to provide a thorough understanding of the present disclosure. However, the present disclosure can also be implemented in other ways than those described herein. Those skilled in the art can make similar generalization without departing from the essence of the present disclosure. Therefore, the present disclosure is not limited by the specific examples disclosed below.

Secondly, the term “one example” or “examples” referred to here refers to specific features, structures, or features that may be included in at least one implementation of the present disclosure. Wherever the phrase “in one embodiment” appears in the specification, it does not necessarily refer to the same embodiment, nor does it imply that the embodiment is separate or mutually exclusive from other embodiments.

### Embodiment 1

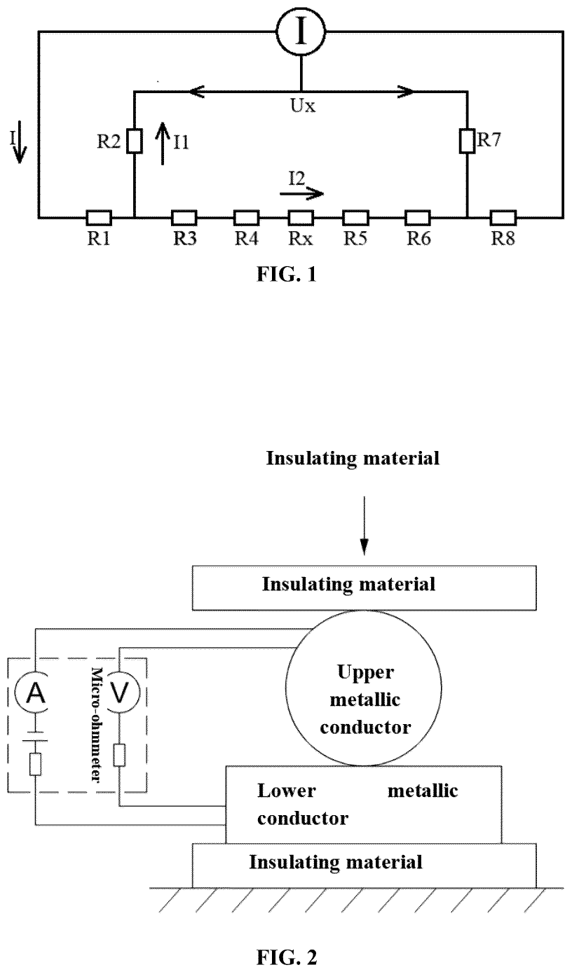

Referring to FIG. 1-3, as a first embodiment of the present disclosure, the embodiment provides a testing method for a contact resistance, for testing a contact resistance between two metallic conductors, including first exerting a given contact pressure to enable two metallic conductors to contact; connecting two ends of a current source with a pair of leads respectively connected with two metallic conductors as an input current; introducing the voltage at two ends of the metallic conductors into a multimeter using another pair of leads to be tested; and calculating a contact resistance value according to the testing result, wherein the input current is a pulse current.

Two ends of the current source are connected with a pair of leads as the input current, and the voltage at two ends of two metallic conductors to be tested is introduced into a multimeter using another pair of leads to be tested. The schematic diagram of testing is as shown in FIG. 1, wherein R1, R2, R7 and R8 are resistors of the leads, R3, R6 is a contact resistance, R4, R5 is a lead resistance of two metallic conductors to be tested, and Ux is a voltage value at two ends of a testing point. Generally the input resistance of a voltmeter is far larger than a tested resistance, and the lead also has a smaller resistance, therefore, testing leads can be approximately taken as I₂=I, that is, the relationship between the voltage values at two ends of the testing point and the contact resistance can be expressed according to the following equation:

$$Ux = I ( {R}_{3} + {R}_{4} + {R}_{5} + {R}_{6} + {R}_{x} )$$

For a micro contact resistance, a smaller current cannot ensure the accuracy of testing results, but if a larger current is continuously introduced, a great deal of Joule heat can be definitely generated, resulting a certain impact on testing results. In addition, along with the testing time, such impact can be more and more apparent. A contact resistance can be tested with a pulse current instead of a continuous current. In a short current introduction time, the temperature generated by even a larger current pulse has a small impact on the resistance of a contact area, therefore, a method for testing the contact resistance with a larger pulse current can both improve the testing accuracy and prevent materials in the contact area from phenomena such as softening.

Furthermore, the exerting the given contact pressure includes, placing the two metallic conductors at the working area of the press machine, adjusting the contact surfaces of the two metallic conductors to be fitted with the pressing direction of the press machine, and adding the insulating material in the pressing direction to isolate the press machine from the metallic conductors. The two metallic conductors used in the embodiment are made of a aluminum alloy material. One of the groups is aluminum alloy rods, in the size of: 40 mm in length, and 20 mm in diameter. Another group is aluminum alloy discs, in the size of: 20 mm in length, and 80 mm in diameter. When exploring the impact of pressures on contact resistances, to prevent roughness from affecting testing results, a method of a same test sample is adopted to ensure a certain value of roughness of an aluminum alloy test sample, a PC-5 press machine is adopted to exert a pressure on the test sample, since the PC-5 pressure machine is a manual hydraulic press machine, with the advantages of stable pressure exerting and high precision. The panel of the press machine can simultaneously display the tonnage and Mpa of the pressure exerted, with the range of 0˜45 MPa. In the testing, the pressure is controlled through pressure intensity. A part of parameters of the PC-5 press machine are as follows:

TABLE 1
Parameters of PC-5 press machine

| Parameter | Value | |
|---|---|---|
| Pressure gage | Dual scale for pressure and pressure intensity | |
| Column spacing | 96*130 | mm |
| Pressure range | 0~45 | MPa |
| Piston diameter | 45 | mm |
| Pressure stability | <=1 MPa/10 min | |
| Diameter of working table | 80 | mm |
| Maximum piston stroke | 30 | mm |
| Instrument weight | 28 | kg |

Preferably, a method for testing contact resistance values at different contact pressures includes, successively increasing the contact pressure between the two metallic conductors by set gradient values; respectively introducing different transient current values as pulse current inputs after pressure increase each time; and taking the mean value of contact resistances tested with different transient currents as contact resistances of corresponding contact pressures. As shown in FIG. 2, the two metallic conductor test samples to be tested, after dust on which is wiped off, are placed on the press machine, an insulating material is placed between the test samples and the press machine, four leads are led out from the test samples and respectively connected with a pair of excitation lines and a pair of testing lines of a micro-ohmmeter, for the micro-ohmmeter to exert the current to test the contact resistance. A Micro-Centurion II micro-ohmmeter is used in the embodiment. In actual operation, the current is introduced from a red thick lead, and flows out from a black thick lead, and two thin leads are used as the testing lines of the micro-ohmmeter. Before each testing, whether the test samples are evenly placed and absolute insulation between the test samples and the press machine is ensured, then the fuel outlet valve of the press machine is clockwise screwed, and the pressure is exerted. When the pressure reaches an appointed value, the start button of the micro-ohmmeter is pressed, a transient testing current is selected for testing and the result is recorded. After a single testing, the micro-ohmmeter is turned off, and the process is repeated to continue the testing.

Furthermore, a variation curve of tested contact resistances along with contact pressures is recorded, and a contact pressure range that the contact resistance trends to be stable along with the contact pressures is taken as a working range. The method for calculating the contact resistance value within the working range of contact pressures includes: calculating a contact resistance value of a single contact spot formed at the given contact pressure, taking the combination of all contact spots formed between the two metallic conductors as a contact surface, and calculating the total contact resistance value of the contact surface as the contact resistance value between the two metallic conductors. Before the testing, the resistances of the aluminum alloy rods and discs are first tested using the micro-ohmmeter, as 1.34 μΩ and 2.35 μΩ respectively. In the testing process, 1 MPa is taken as the gradient, and the pressure intensity of 1˜30Mpa is exerted. After each pressure intensity exerting, the contact resistances between the aluminum alloy test samples are recorded with the transient testing currents 10 A, 20 A, 50 A, 100 A, 200 A of the micro-ohmmeter, and the average value of the five groups is taken as the final testing result. In the testing process, movement between the leads and the aluminum alloy test samples is prevented as much as possible, thereby preventing errors of the testing result caused by different contact positions of the leads and the test samples. After the testing, the testing result is drawn as shown in FIG. 3.

As shown in FIG. 3, along with the increase of the pressure, the contact resistance of the aluminum alloy test sample trends to decrease continuously. In addition, when the pressure is small, the rate that the contact resistance of the aluminum alloy test sample decreases is large, along with continuous increase of the pressure, the rate that the contact resistance between the test samples decreases is reduced, and trends to be stable finally, since when the pressure is small, the aluminum alloy rods and the discs are not in full contact, the contact area can be rapidly increased if the pressure is exerted at the moment, resulting in rapid decrease of the contact resistance value between the test samples. When the pressure reaches 15 MPa, the aluminum alloy test samples are in full contact, the effective contact area is hard to increase if the pressure is increased at the moment, the area of contact spot is stabilized, and finally the contact resistance value of the aluminum alloy test sample is stabilized, maintained around 15 μΩ. The sum of resistance values of the aluminum alloy rods and discs separately tested before the testing is 3.69 μΩ, which is far smaller than the minimum value of tested contact resistances, indicating that in the contact process of the aluminum alloy rods and discs, the contact resistance is the main source of a total resistance, and the resistance of the conductor self only accounts for a small percent of the total resistance.

The embodiment provides a testing method for acquiring a stable contact pressure, ensuring that the stable contact pressure is acquired, the test samples can be in full contact, and a contact pressure range appropriate for testing is found, thus bringing convenience for subsequent testing and calculation.

### Embodiment 2

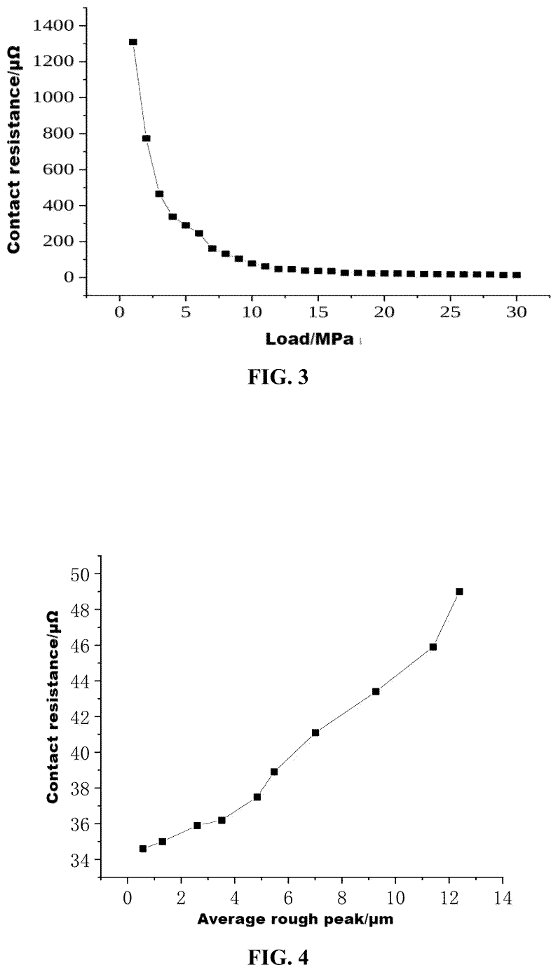

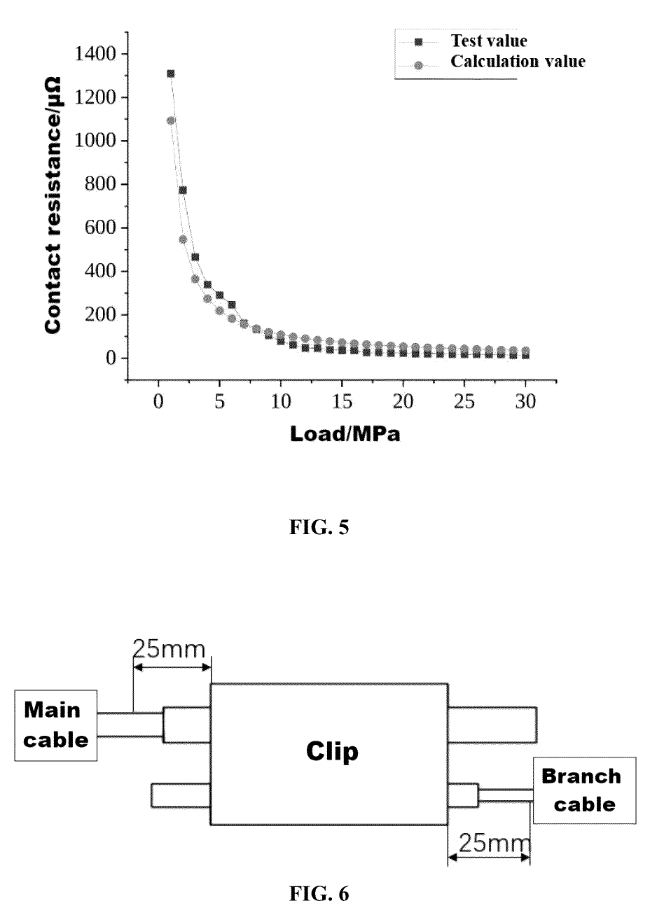

Referring to FIG. 4-5, as a second embodiment of the present disclosure, the difference from the former embodiment lies in that the contact spots between the two metallic conductors are taken as a circle, and the equation for calculating the contact resistance of a single contact spot between two metallic conductors is:

$${R}_{c} = {R}_{s} + {R}_{f} = ( {ρ}_{1} + {ρ}_{2} ) / 4 r + \frac{θ}{π {r}^{2}}$$

in the equation, the first term is the calculation equation of a cold-state contraction resistance Rₛ of the two metallic conductors at 0° C.; the second term is the calculation equation of a film resistance R_{f} formed on the contact surface of the two metallic conductors; ρ₁ and ρ₂ are respectively resistivities of the two metallic conductors in mutual contact; r represents an equivalent radius of the contact spot of the two metallic conductors; and θ is a film resistivity of a pollution film on the contact surface of the two metallic conductors.

Specifically, the two metallic conductors both take the shape of a cylinder, and the two metallic conductors are in contact in the mode of line contact between a cylindrical side surface with a cylindrical bottom surface, or surface contact between a cylindrical bottom surface with a cylindrical bottom surface.
the calculation equation of the radius r₁ of the contact surfaces of the two cylindrical metallic conductors is:

$${r}_{1} = {( 4 P r / π {E}^{*} )}^{\frac{1}{2}}$$

in the equation, P represents a contact pressure; E* represents an equivalent elastic modulus; r represents an equivalent contact radius of a single contact spot;
the calculation equations of an equivalent elastic modulus E* and an equivalent contact radius r of the single contact spot are as follows:

$${E}^{*} = \frac{1 - {μ}_{1}^{2}}{{E}_{1}} + \frac{1 - {μ}_{2}^{2}}{{E}_{2}}$$

$$\frac{1}{r} = \frac{1}{{R}_{1}} + \frac{1}{{R}_{2}}$$

in the equation, E₁ and E₂ respectively represent elastic moduli of the two metallic conductors in contact; μ₁ and μ₂ represent the Poisson's ratio of the two conductors in contact; and R₁ and R₂ respectively represent the radii of the two cylindrical metallic conductors in mutual contact. In the embodiment, test samples same as those in the embodiment 1 are used, the pressure 15 Mpa exerted by the press machine is ensured, the transient testing current introduced by the micro-ohmmeter is set as 100A, and data is processed and the graph is drawn as shown in FIG. 4 after the testing. As shown in FIG. 4, along with increase of roughness, the contact resistance of the aluminum alloy test sample trends to increase, and the difference between the maximum contact resistance value and the minimum contact resistance value is 14.5 μΩ. Since when the pressure is certain, along with increase of a roughness peak, the contact area of a convex part decreases, and the contraction resistance of the current in the contact surface is increased.

Furthermore, when the two cylindrical metallic conductors are in line contact, the two metallic conductors are taken as that multiple successive equivalent contact spots are taken as the contact surfaces, and the calculation equation of the total contact resistance of the contact surfaces of the two metallic conductors at the moment is:

$${R}_{c} = {R}_{s} * \frac{b}{r}$$

in the equation, R_{c} represents the total contact resistance; Rₛ is a contraction resistance of a single contact spot; b represents the length of the contact surface; r represents the radius of the single contact spot;
the calculation equation of a hot-state contraction resistance R_{sθ} of the single contact spot is:

$${R}_{s θ} = {R}_{s 0} + ( 1 + \frac{2}{3} α T )$$

in the equation, Rₛ₀ is a cold-state contraction resistance at 0° C.; T is the contact surface temperature; and a is the temperature coefficient of the resistance.

In the embodiment, the elastic modulus E₁=E₂=6.9e¹⁰ and the Poisson's ratio μ₁=μ₂=0.33, R₁=0.02, R₂=∞ are taken, the values are substituted into the equation to calculate the contact resistances of the aluminum alloy test samples at different pressures, and the calculation value and the testing values are drawn into the graphs as shown in FIG. 5.

As shown in FIG. 5, the contact resistance value calculated by the method has a good fit with the contact resistance value tested. Moreover, along with the increase of the load, a better fit effect of curves is achieved, since the impact of the film resistance upon the contact resistance is ignored during calculation. When the load is less than a certain value, due to the impact of the film resistance, the testing result can be greater than the calculation value. Along with increase of the load, micro-ridges on a metal surface start to penetrate an oxide film to form electrical contact between metals. The error between the calculation value and the testing value of the contact resistance is decreased if the load is increased at the moment. Therefore, the calculation equations of the testing method are verified and have good reference value, and can be used for calculating contact resistance values in a simulated actual usage environment.

Other structures are identical to those of embodiment 1.

In the embodiment, by testing, the contact resistance value obtained through calculation is compared and verified with a contact resistance value actually tested, thereby deducing calculation equations for simulating contact resistance values in usage environments at different contact pressures and different contact surface temperatures.

### Embodiment 3

Referring to FIG. 6-9, as a third embodiment of the present disclosure, the difference from the former embodiment lies in that the embodiment provides a testing loop for a contact resistance, for achieving the testing method for the contact resistance, including two groups of cables to be tested, a current source for providing an input current and a multimeter for testing the voltage at two ends of the cables to be tested;
a loop is formed between the two groups of cables to be tested and the current source and the multimeter though a lead; the contact resistance is generated between the two groups of cables to be tested after in contact; and the multimeter is in parallel connection with the two groups of cables to be tested.

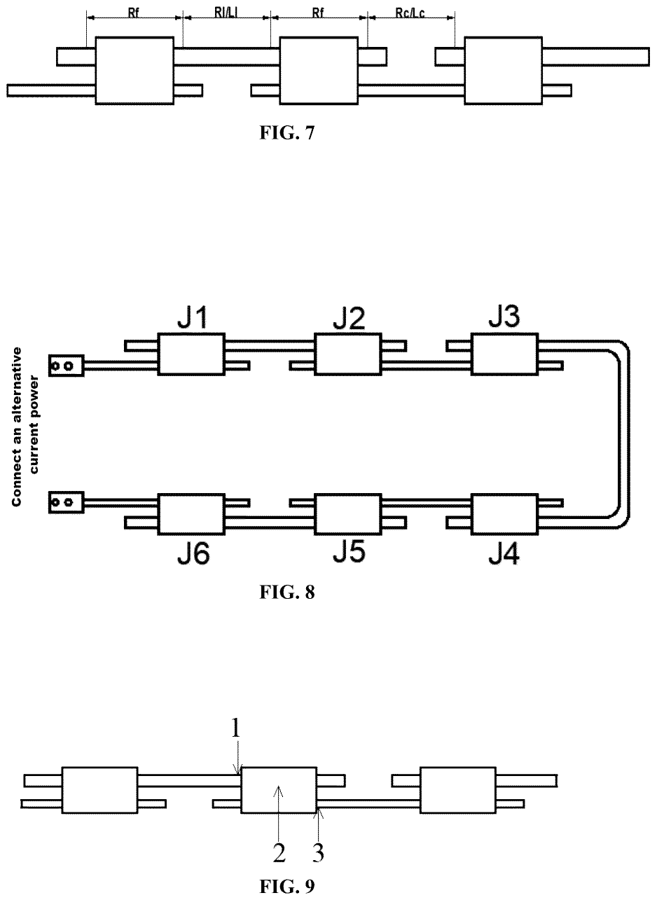

In the embodiment, the micro-ohmmeter is also used to test the contact resistance. Since the contact resistance value tested is very low, the impact of a self-resistance of a lead upon the contact resistance shall be considered. In testing design, a method of subtracting a lead resistance from the total resistance is adopted to obtain an accurate value of the contact resistance, and a method of testing twice, once in the forward direction and once in the reverse direction, is used to eliminate the impact of thermoelectric potential. In addition, the position of a potential testing point when testing a clip resistance is specified to be on a lead at the end of the clip, the position of electrical testing of the contact resistance is as shown in FIG. 6. The testing theory of testing the contact resistance using the Micro-Centurion II micro-ohmmeter is shown in FIG. 7.

The contact resistance tested is determined according to the following equation:

$${R}_{t} = {R}_{f} - \frac{{R}_{L} l}{{L}_{L}} - \frac{{R}_{C} l}{{L}_{C}}$$

In the equation: R_{f} is a resistance value tested between two ends of the clip, in Ω; R_{L} is a tested resistance value of a main lead, in Ω; L_{L}−R_{L} is a corresponding length of the main lead, in mm; R_{C} is a tested resistance value of a branch lead, in Ω; L_{C}−R_{C} is a corresponding length of the branch lead, in Ω; and Lis the distance between the potential testing point and the end of the clip, taking 25 mm.

Preferably, at least three groups of cables to be tested are set and are sequentially connected through ends. Two adjacent groups of cables to be tested are in connection and contact through a group of connecting clips. The current source is a large current generator connected at the head and tail ends of the cables to be tested and connected sequentially. Each group of the connecting clips maintains two groups of cables to be tested in contact by a given contact pressure. To prevent a single clip from affecting the testing result, and simulate the operation situation in the working process actually as much as possible, 6 same connecting tubes, 3 150 mm² cables of 95 cm in length and 4 70 mm² cables of 85 cm in length are adopted to establish the testing loop in the embodiment. When the loop is established, ensure that cables between clips are long enough, then the temperatures between the clips are not affected mutually, and overall, the theory of the testing loop is as shown in FIG. 8.

To accurately describe the temperature distribution at each position of the connecting tubes, the arrangement of temperature testing points is of crucial importance. In the testing of the embodiment, a total of 3 temperature testing points are set on the surface of the connecting tubes, the main cable, and an auxiliary cable to investigate the temperature distribution and temperature rise trend of the connecting tubes. The schematic diagram of the temperature testing points is as shown in FIG. 9. In the figure, the testing point 1 is the temperature testing point between the clip and the end of the main lead, the testing point 2 is a temperature testing point in the middle of the clip, and the testing point 3 is a temperature testing point between the clip and the end of the auxiliary lead. Before and after each testing, temperatures in the middle of the connecting tube, at ends of the main lead of the connecting tube and at ends of the auxiliary lead of the connecting tube are recorded, and the hot-state contraction resistance can be calculated with the highest value of the testing temperatures.

Other structures are identical to those of embodiment 2.

Testing process: before the testing, 6 connecting tubes which are clean and free of crack on the surfaces are selected, 3 150 mm² cables of 95 cm in length and 4 70 mm² cables of 85 cm in length are made with cable cutters and meter rulers, the cables are fixed with the connecting clips, insulating layers of the cables to be in contact with the connecting tubes are stripped off with rotary cutting type wire strippers, and to ensure the accurate testing result, the stripping part of each section of the insulating layer is not greater than 30 mm. The connecting tubes, the main lead and the auxiliary lead are placed on a bench screw to be pre-fixed, subsequently a pre-tension is exerted to bolts with a digital torque wrench, identical pre-tensions are ensured as much as possible at two bolts during clamping, and a serial connection method is adopted to introduce the large current generator into the loop. After the whole testing loop is established, the large current generator is started and relevant parameters are set for testing.

The testing process includes three stages of introducing power and raising the temperature of a clip loop, stabilizing the temperature and cutting off the power supply to cool down. At the stage of introducing power and raising the temperature of the clip loop, the clip is heated with a working frequency alternative current generated by the large current generator, and the current introduced is smaller than a rated current which can be endured by the lead. When the fluctuation of the temperature of the clip within 15 min is not greater than 2° C., it regards that the loop temperature reaches a stable stage. At the moment, the temperature testing points of the connecting tubes and the leads are tested with a thermal infrared imager, and testing data is recorded. Then the large current generator is turned off to reduce the current to zero, the loop then enters into the cooling stage, till the room temperature after cooling, a next testing is prepared, and each testing is carried out for three times.

The embodiment provides a method for acquiring a contact surface temperature at different stages at different testing points, thus the calculated contact resistance value is more fitted with the usage environment.

It should be noted that the above embodiments are merely used to explain the technical solutions of the present disclosure and not intended to limit the present disclosure. Although the present disclosure is described in detail with reference to the preferred embodiments, those of ordinary skill in the art should understand that they can make modifications or equivalent substitutions to the technical solutions of the present disclosure without departing from the spirit and scope of the technical solutions of the present disclosure. These modifications or equivalent substitutions should fall within the scope of the claims of the present disclosure.

What is claimed is:

1. A testing method for a contact resistance, for testing a contact resistance between two metallic conductors, comprising:
exerting a given contact pressure to enable two metallic conductors to contact;
connecting two ends of a current source with a pair of leads respectively connected with two metallic conductors as an input current;
introducing the voltage at two ends of the metallic conductors into a multimeter using another pair of leads to be tested; and
calculating a contact resistance value according to the testing result,
wherein the input current is a pulse current.

2. The testing method for the contact resistance according to claim 1, wherein the exerting a given contact pressure comprises:
placing two metallic conductors at the working area of a press machine;
adjusting the contact surfaces of the two metallic conductors to be fitted with the pressing direction of the press machine; and
adding an insulating material in the pressing direction to isolate the press machine from the metallic conductors.

3. The testing method for the contact resistance according to claim 2, further comprising testing the contact resistance value at different contact pressures, comprising:
successively increasing the contact pressure between the two metallic conductors by set gradient values;
respectively introducing different transient current values as pulse current inputs after pressure increase each time; and
taking the mean value of contact resistances tested with different transient currents as contact resistances of corresponding contact pressures.

4. The testing method for the contact resistance according to claim 3, further comprising:
recording a variation curve of tested contact resistances along with contact pressures;
taking a contact pressure range that the contact resistance trends to be stable along with the contact pressures as a working range;
a method for calculating the contact resistance value within the working range of contact pressures comprises:
calculating a contact resistance value of a single contact spot formed at the given contact pressure;
taking the combination of all contact spots formed between the two metallic conductors as a contact surface; and
calculating the total contact resistance value of the contact surface as the contact resistance value between the two metallic conductors.

5. The testing method for the contact resistance according to claim 4, wherein by taking the contact spots between the two metallic conductors as a circle, the equation for calculating the contact resistance of a single contact spot between two metallic conductors is:
$${R}_{c} = {R}_{s} + {R}_{f} = ( {ρ}_{1} + {ρ}_{2} ) / 4 r + \frac{θ}{π {r}^{2}} ;$$
in the equation, the first term is the calculation equation of a cold-state contraction resistance Rₛ of the two metallic conductors at 0° C.; the second term is the calculation equation of a film resistance R_{f} formed on the contact surface of the two metallic conductors; ρ₁ and ρ₂ are respectively resistivities of the two metallic conductors in mutual contact; r represents an equivalent radius of the contact spot of the two metallic conductors; and θ is a film resistivity of a pollution film on the contact surface of the two metallic conductors.

6. The testing method for the contact resistance according to claim 5, wherein the two metallic conductors both take the shape of a cylinder; the two metallic conductors are in contact in the mode of line contact between a cylindrical side surface with a cylindrical bottom surface, or surface contact between a cylindrical bottom surface with a cylindrical bottom surface;
the calculation equation of the radius r₁ of the contact surfaces of the two cylindrical metallic conductors is:
$${r}_{1} = {( 4 P r / π {E}^{*} )}^{\frac{1}{2}}$$
in the equation, P represents a contact pressure; E* represents an equivalent elastic modulus; r represents an equivalent contact radius of a single contact spot;
the calculation equations of an equivalent elastic modulus E* and an equivalent contact radius r of the single contact spot are as follows:
$${E}^{*} = \frac{1 - {μ}_{1}^{2}}{{E}_{1}} + \frac{1 - {μ}_{2}^{2}}{{E}_{2}}$$
$$\frac{1}{r} = \frac{1}{{R}_{1}} + \frac{1}{{R}_{2}}$$
in the equation, E₁ and E₂ respectively represent elastic moduli of the two metallic conductors in contact; μ₁ and μ₂ represent the Poisson's ratio of the two conductors in contact; and R₁ and R₂ respectively represent the radii of the two cylindrical metallic conductors in mutual contact.

7. The testing method for the contact resistance according to claim 6, wherein when the two cylindrical metallic conductors are in line contact, the two metallic conductors are taken as that multiple successive equivalent contact spots are taken as the contact surfaces, and the calculation equation of the total contact resistance of the contact surfaces of the two metallic conductors at the moment is:
$${R}_{c} = {R}_{s} * \frac{b}{r}$$
in the equation, R_{c} represents the total contact resistance; Rₛ is a contraction resistance of a single contact spot; b represents the length of the contact surface; r represents the radius of the single contact spot;
the calculation equation of a hot-state contraction resistance R_{sθ} of the single contact spot is:
$${R}_{s θ} = {R}_{s 0} + ( 1 + \frac{2}{3} α T )$$
in the equation, Rₛ₀ is the cold-state contraction resistance at 0° C.; T is the contact surface temperature; and α is the temperature coefficient of the resistance.

8. The testing method for the contact resistance according to claim 7, wherein the method for acquiring a contact surface temperature comprises:
enabling two metallic conductors to contact at a given contact pressure through a connecting clip; and
inputting a pulse current at two ends of the two metallic conductors, and acquiring the temperature of a testing point;
wherein the testing point at least comprises the middle of the connecting clip, and the connecting parts of the connecting clip with the two metallic conductors.

9. A testing loop for a contact resistance, for achieving the testing method for the contact resistance according to claim 8, comprising two groups of cables to be tested, a current source for providing input current, and a multimeter for testing the voltage at two ends of the cables to be tested;
a loop is formed between the two groups of cables to be tested and the current source and the multimeter though a lead; the contact resistance is generated between the two groups of cables to be tested after in contact; and the multimeter is in parallel connection with the two groups of cables to be tested.

10. The testing loop for the contact resistance according to claim 9, wherein at least three groups of cables to be tested are set and sequentially connected through ends; two adjacent groups of cables to be tested are in connection and contact through a group of connecting clips;
the current source is a large current generator connected at the head and tail ends of the cables to be tested and connected sequentially; and each group of the connecting clips maintains two groups of cables to be tested in contact by a given contact pressure.
